(19) United States
(12) Patent Application Publication
(10) Pub. No.: US 2024/0321653 A1
(43) Pub. Date: Sep. 26, 2024

(54) WAFER PACKAGE FOR PROTECTION OF ALUMINUM DIE PAD OF DIE FROM DAMAGES DURING PROBE TESTING PROCESS

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/613,122

(22) Filed: Mar. 22, 2024

(30) Foreign Application Priority Data
Mar. 24, 2023 (TW) 112111205

(51) Int. Cl. H01L 21/66; G01R 31/28; H01L 23/00

(52) U.S. Cl. CPC H01L 22/32; G01R 31/2831; H01L 24/03; H01L 24/05; H01L 24/48; H01L 2224/03464; H01L 2224/05572; H01L 2224/05624; H01L 2224/05644; H01L 2224/05664; H01L 2224/48105; H01L 2224/48227

(57) ABSTRACT

A wafer package for protection of an aluminum die pad of a die from damages during probe testing process is provided. Before performing the probe testing process on a plurality of dies of the wafer package, at least one bump is disposed on a surface of the aluminum die pad of the die of the wafer package by electroless plating. The bump is a metal stack structure having a certain thickness and composed of a nickel layer and a gold layer stacked over the aluminum die pad in turn, or a nickel layer, a palladium layer, and a gold layer stacked over the aluminum die pad in turn. Thus structural strength of the aluminum die pad of the die is increased to prevent damages during the probe testing process. Therefore, quality and reliability of the dies in following operations such as wire bonding are increased.

### CROSS-REFERENCE TO RELATED APPLICATIONS

This non-provisional application claims priority under 35 U.S.C. § 119(a) on Patent Application No(s). 112111205 filed in Taiwan, R.O.C. on Mar. 24, 2023, the entire contents of which are hereby incorporated by reference.

### BACKGROUND OF THE INVENTION

The present invention relates to a wafer package, especially to a wafer package in which at least one bump is disposed over at least one aluminum die pad of respective dies before probe testing process for protection of a surface of the aluminum die pad of the die from damages during the probe testing process.

In semiconductor industry, probe testing is performed after completing production of wafers and before preparation of following operations such as addition of a redistribution layer (RDL). A probe is in contact with an aluminum die pad of a chip on the wafer to establish an electrical connection for testing. Refer to FIG. 8, a surface 5a of a wafer 5 available now is provided a plurality of dies 5b each of which is arranged with at least one aluminum die pad 5c and at least one passivation layer 5d. While performing the probe testing of the wafer 5, at least one probe 3 is used to contact and electrically connect with the respective aluminum die pads 5c for testing and sending electrical signals to related test equipment to analyze functions, features, or conditions of the respective dies 5b and screen out defective products. A cutting process of the wafer 5 is performed after completing the probe testing and the wafer 5 is divided into a plurality of die package units 5e each of which is used for wire bonding or other welding process. As shown in FIG. 10, take wire bonding as an example but not limited. By a bonding wire 4 which forms a first bond 4a and a second bond 4b respectively on the aluminum die pad 5c and an external electronic component 2, the respective die package units 5e are electrically connected with the electronic component 2. However, a positive pressure (as arrow N in FIG. 8 indicates) is generated while the probe 3 is in contact with the respective aluminum die pads 5c so that a dent is left on a surface of the aluminum die pad 5c which is made of soft metals (as shown in FIG. 9 and FIG. 10). Then quality and reliability of the respective dies 5b in the following operations such as wire bonding or other welding process are further affected.

### SUMMARY OF THE INVENTION

Therefore, it is a primary object of the present invention to provide a wafer package which protects an aluminum die pad of a die from damages during probe testing process. Before performing the probe testing process on a plurality of dies of the wafer package, at least one bump is formed on a surface of at least one aluminum die pad of the die of the wafer package by electroless plating. The bump is a metal stack structure having a certain thickness and composed of a nickel layer and a gold layer stacked over the aluminum die pad in turn, or a nickel layer, a palladium layer, and a gold layer stacked over the aluminum die pad in turn. Thus structural strength of the aluminum die pad of the die is increased to prevent possible damages during the probe testing process. Therefore, the problem of a dent left on the aluminum die pad by a probe during the probe testing process can be solved effectively.

In order to achieve the above object, a wafer package which protects an aluminum die pad of a die from damages during probe testing process according to the present invention is provided. The wafer package includes a plurality of dies, at least one dielectric layer, and a plurality of bumps. The respective dies are disposed on a surface of the wafer package and arranged in an array. Each of the dies is provided with at least one aluminum die pad and at least one passivation layer. The dielectric layer is disposed on the surface of the wafer package and provided with at least one opening corresponding to the aluminum die pad of the die. The aluminum die pad is electrically connected to the outside through the corresponding opening. The respective bumps are formed in the respective openings of the dielectric layer by electroless plating technique and electrically connected with the aluminum die pad in the opening. The bump is a metal stack structure composed of a nickel (Ni) layer and a gold (Au) layer stacked over the aluminum die pad in turn and having a certain thickness, or a metal stack structure composed of a nickel (Ni) layer, a palladium (Pd) layer, and a gold (Au) layer stacked over the aluminum die pad in turn and having a certain thickness. Thus structural strength of the aluminum die pad of the die is increased so that the aluminum die pad is not damaged easily during the probe testing process. A method of manufacturing the wafer package according to the present invention includes the following steps. Step S1: providing a wafer package which includes a plurality of dies arranged in an array and located on a surface of the wafer package. Each of the dies is provided with at least one aluminum die pad and at least one passivation layer. Step S2: disposing at least one dielectric layer on the surface of the wafer package before performing probe testing process on the dies of the wafer package. The dielectric layer consists of at least one opening corresponding to the aluminum die pad of the die. The aluminum die pad is electrically connected with the outside through the opening. Step S3: forming at least one bump in the opening of the dielectric layer by electroless plating technique. The bump is electrically connected with the aluminum die pad in the opening. The bump is a metal stack structure composed of a nickel (Ni) layer and a gold (Au) layer stacked over the aluminum die pad in turn and having a certain thickness, or a metal stack structure composed of a nickel (Ni) layer, a palladium (Pd) layer, and a gold (Au) layer tacked over the aluminum die pad in turn and having a certain thickness. The above design helps improve quality and reliability of the respective dies in the following operations and thus market competitiveness of products is increased.

Preferably, after the step S2, the method further including a step of dividing during which the wafer package is separated into a plurality of die package units using a cutting tool.

Preferably, the respective die package units are used for wire bonding operation. By a bonding wire which forms a first bond and a second bond respectively on the bump of the die package unit and an external electronic component, the die package unit and the external electronic component are electrically connected.

### BRIEF DESCRIPTION OF THE DRAWINGS

FIG. 1 is a side sectional view of a wafer package of an embodiment according to the present invention;

FIG. 2 is a side sectional view of a die package unit of an embodiment according to the present invention;

FIG. 3 is a side sectional view of a chip package of another embodiment according to the present invention;

FIG. 4 is a side sectional view of a die package unit of another embodiment according to the present invention;

FIG. 5 is a schematic drawing showing a partial top view of a die package unit of an embodiment according to the present invention;

FIG. 6 is a side sectional view showing electrical connection between a die package unit of an embodiment and an electronic component according to the present invention;

FIG. 7 is a side sectional view showing electrical connection between a die package unit of another embodiment and an electronic component according to the present invention;

FIG. 8 is a side sectional view of a wafer available now;

FIG. 9 is a schematic drawing showing a partial top view of a wafer available now;

FIG. 10 is a side sectional view showing electrical connection between a die package unit divided from a wafer available now and an electronic component according to the present invention.

### DETAILED DESCRIPTION OF THE PREFERRED EMBODIMENT

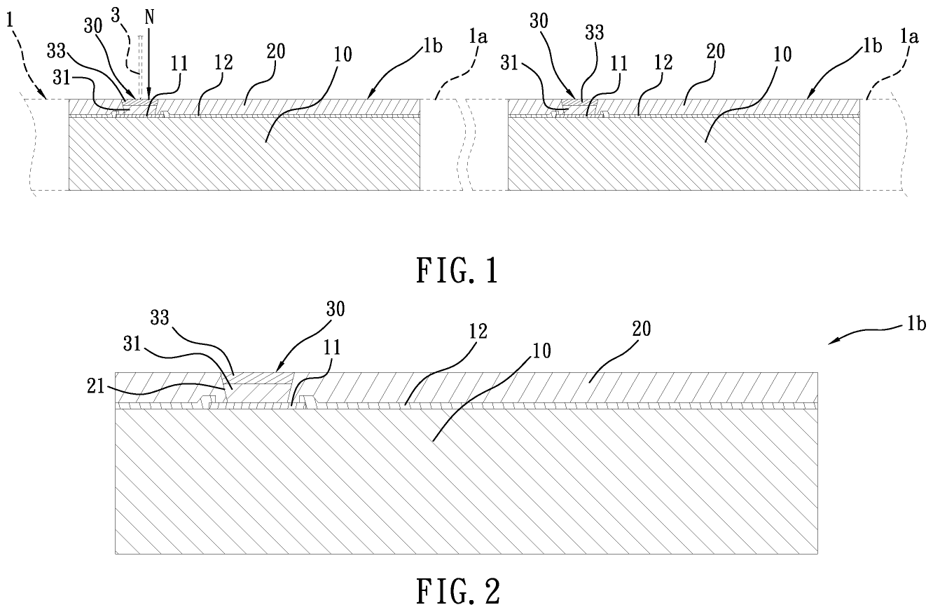

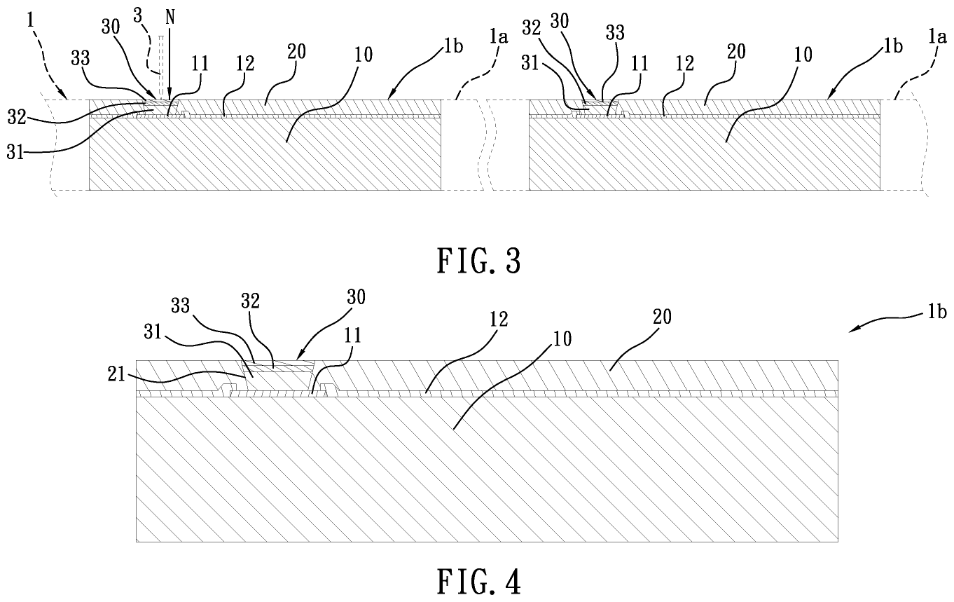

Refer to FIG. 1 and FIG. 3, a wafer package 1 for protection of an aluminum die pad of a die from damages during probe testing process according to the present invention is provided. The wafer package 1 includes a plurality of dies 10, at least one dielectric layer 20, and a plurality of bumps 30.

The respective dies 10 are disposed on a surface 1a of the wafer package 1 and arranged in an array. Each of the dies 10 is provided with at least one aluminum die pad 11 and at least one passivation layer 12.

The dielectric layer 20 is arranged at the surface 1a of the wafer package 1 and provided with at least one opening 21 corresponding to the aluminum die pad 11 of the die 10. The respective aluminum die pads 11 are electrically connected to the outside through the corresponding openings 21.

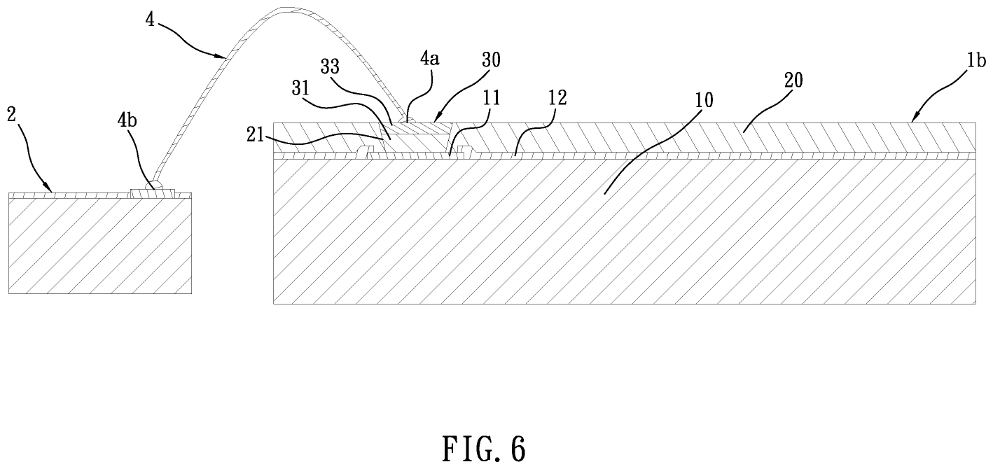

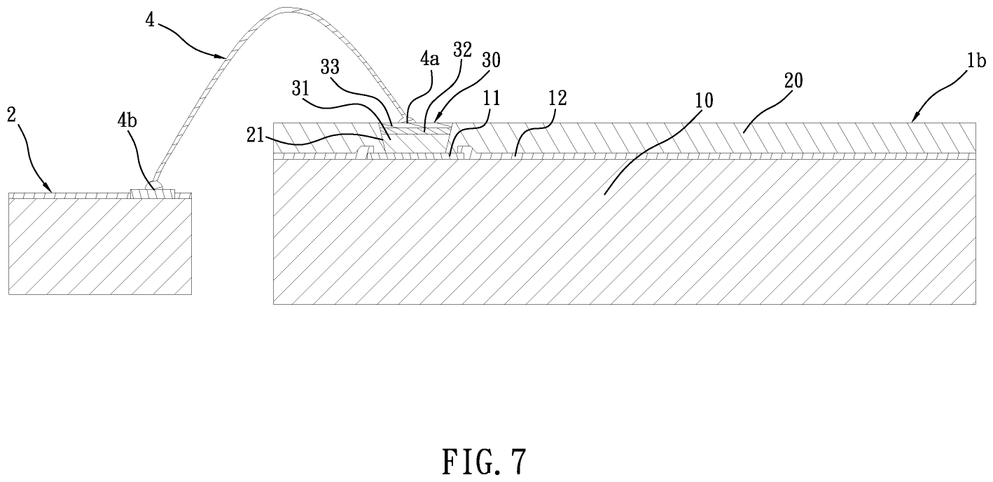

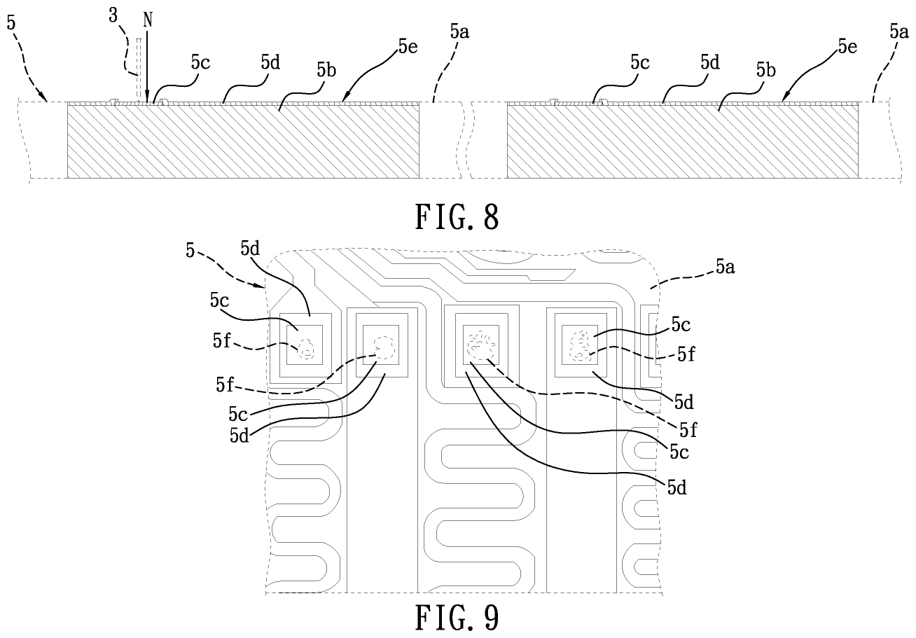

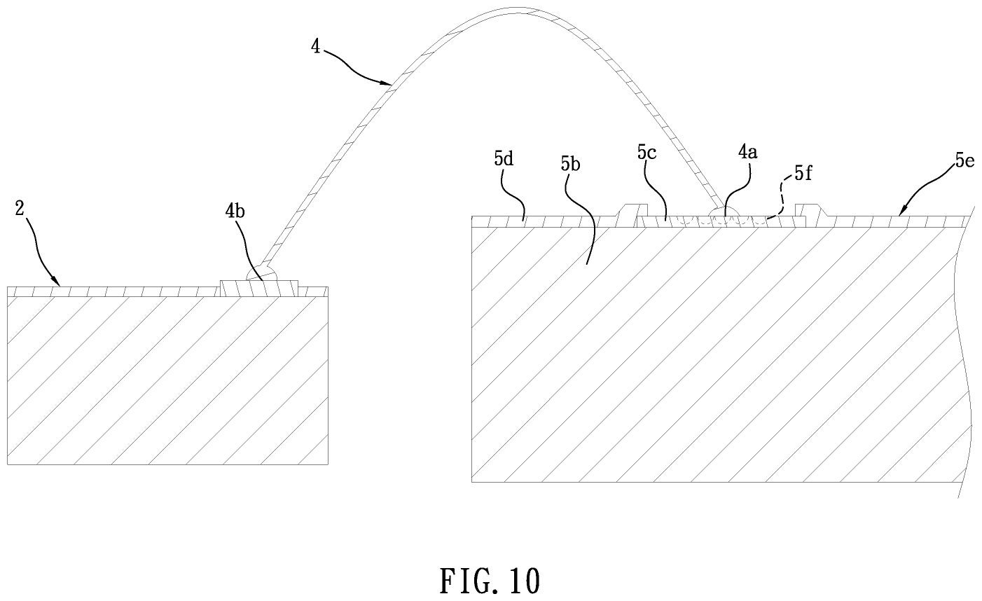

The respective bumps 30 are formed in the respective openings 21 of the respective dielectric layer 20 by electroless plating technique and electrically connected with the respective aluminum die pads 11 in the openings 21. Each of the bumps 30 is a metal stack structure composed of a nickel (Ni) layer 31 and a gold (Au) layer 33 stacked over the aluminum die pad 11 in turn and having a certain thickness, as shown in FIG. 1, FIG. 2, and FIG. 6 or a metal stack structure composed of a nickel (Ni) layer 31, a palladium (Pd) layer 32, and a gold (Au) layer 33 stacked over the aluminum die pad 11 in turn and having a certain thickness, as shown in FIG. 3, FIG. 4, and FIG. 7. Thereby structural strength of the aluminum die pad 11 of the die 10 is increased so that the aluminum die pad 11 is protected from damages during the probe testing process.

The gold (Au) layer 33 forms only a part of the bump 30 while the rest part of the bump 30 is formed by the nickel (Ni) layer 31, as shown in FIG. 2, or a combination of the nickel (Ni) layer 31 with the palladium (Pd) layer 32, as shown in FIG. 4. By such composition, the amount of the gold (Au) layer 33 with higher cost used can be reduced while the structural strength of the respective bump 30 remains, without losing a certain structural strength. The design is beneficial to reduction of manufacturing cost.

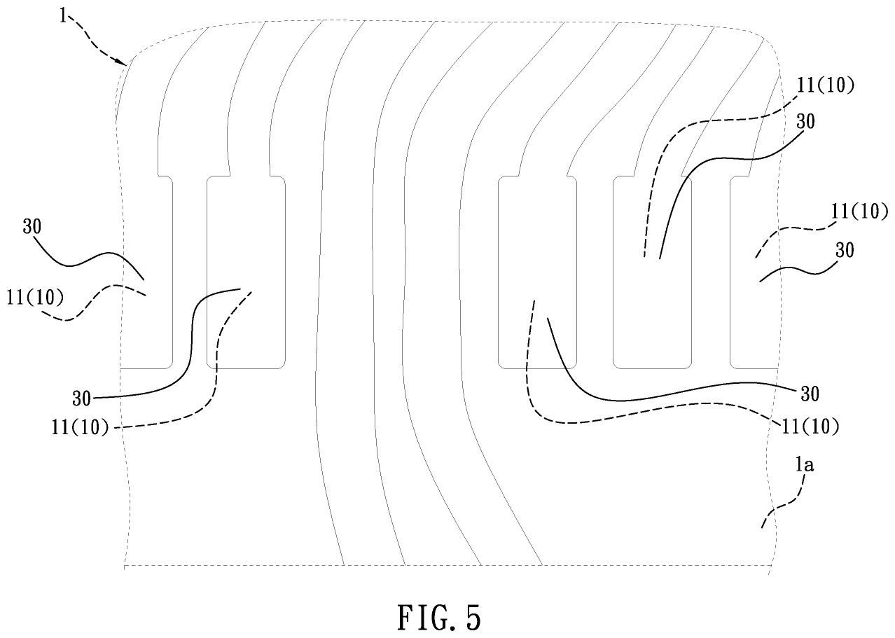

After performing the probe testing process on the wafer package 1, the respective bumps 30 replace the respective aluminum die pads 11 of the dies 10 to withstand a positive pressure from a probe 3, as an arrow N shown in FIG. 1 and FIG. 3 indicates. Thus there is no dent left on the aluminum die pad 11 of the die 10, and even no dent left on the respective bumps 30, but not limited, as shown in FIG. 5.

A method of manufacturing the wafer package 1 according to the present invention includes the following steps.

Step S1: providing a wafer package 1 which includes a plurality of dies 10 arranged in an array and located on a surface 1a of the wafer package 1. Each of the dies 10 is provided with at least one aluminum die pad 11 and at least one passivation layer 12, as shown in FIG. 1 and FIG. 3.

Step S2: disposing at least one dielectric layer 20 on the surface 1a of the wafer package 1 before performing a probe testing process on the dies 10 of the wafer package 1. The dielectric layer 20 is provided with at least one opening 21 corresponding to the aluminum die pad 11 of the die 10. The aluminum die pad 11 is electrically connected with the outside through the opening 21, as shown in FIG. 1 and FIG. 3.

Step S3: forming at least one bump 30 in the opening 21 of the dielectric layer 20 by electroless plating technique. The bump 30 is electrically connected with the aluminum die pad 11 in the opening 21. The bump 30 is a metal stack structure composed of a nickel (Ni) layer 31 and a gold (Au) layer 33 stacked over the aluminum die pad 11 from bottom to top in turn and having a certain thickness, as shown in FIG. 1 and FIG. 2, or a metal stack structure composed of a nickel (Ni) layer 31, a palladium (Pd) layer 32, and a gold (Au) layer 33 stacked over the aluminum die pad 11 from bottom to top in turn and having a certain thickness, as shown in FIG. 3 and FIG. 4.

Moreover, after the step S2, the method further including a step of dividing during which the wafer package 1 (as shown in FIG. 1 and FIG. 3) is separated into a plurality of die package units 1b (as shown in FIG. 2 and FIG. 4) using a cutting tool. As shown in FIG. 6 and FIG. 7, the respective die package units 1b are used for wire bonding operation. By a bonding wire 4 which forms a first bond 4a and a second bond 4b respectively on the bump 30 of the die package unit 1b and an external electronic component 2, the die package unit 1b and the external electronic component are electrically connected, as shown in FIG. 6 and FIG. 7.

1. A wafer package for protection of an aluminum die pad of a die from damages during probe testing process comprising:
a plurality of dies each of which is disposed in an array on a surface of the wafer package and provided with at least one aluminum die pad and at least one passivation layer;
at least one dielectric layer arranged at the surface of the wafer package and provided with at least one opening corresponding to the aluminum die pad of the die; the aluminum die pad is electrically connected to the outside through the opening; and
a plurality of bumps each of which is formed in the opening of the dielectric layer correspondingly by electroless plating and electrically connected with the aluminum die pad in the opening;
the bump is a metal stack structure composed of a nickel (Ni) layer and a gold (Au) layer stacked over the aluminum die pad in turn and having a certain thickness, or a metal stack structure composed of a nickel (Ni) layer, a palladium (Pd) layer, and a gold (Au) layer stacked over the aluminum die pad in turn and having a certain thickness; thus structural strength of the aluminum die pad of the die is increased to protect the aluminum die pad from damages during the probe testing process;
wherein a method of manufacturing the wafer package comprising the steps of:
Step S1: providing a wafer package which includes a plurality of dies arranged in an array and located on a surface of the wafer package;
each of the dies is provided with at least one aluminum die pad and at least one passivation layer;
Step S2: disposing at least one dielectric layer on the surface of the wafer package before performing probe testing process on the dies of the wafer package; the dielectric layer having at least one opening corresponding to the aluminum die pad of the die and the aluminum die pad is electrically connected with the outside through the opening; and
Step S3: mounting at least one bump in the opening of the dielectric layer by electroless plating; the bump is electrically connected with the aluminum die pad in the opening; the bumps is a metal stack structure composed of a nickel (Ni) layer and a gold (Au) layer stacked over the aluminum die pad in turn and having a certain thickness, or a metal stack structure composed of a nickel (Ni) layer, a palladium (Pd) layer, and a gold (Au) layer tacked over the aluminum die pad in turn and having a certain thickness.

2. The wafer package as claimed in claim 1, wherein the method further includes a step of dividing during which the wafer package is separated into a plurality of die package units by a cutting tool.

3. The wafer package as claimed in claim 2, wherein the die package unit is provided for wire bonding; the die package unit and the external electronic component are electrically connected by a bonding wire which forms a first bond and a second bond respectively on the bump of the die package unit and an external electronic component.
